(19) United States
(12) Patent Application Publication
(10) Pub. No.: US 2026/0068456 A1
(43) Pub. Date: Mar. 5, 2026

(54) DISPLAY DEVICE

(71) Applicant: Samsung Display Co., Ltd., YONGIN-SI (KR)

(72) Inventors: SUNKWUN SON, Yongin-si (KR); CHEOL-GON LEE, Yongin-si (KR)

(21) Appl. No.: 19/256,358

(22) Filed: Jul. 1, 2025

(30) Foreign Application Priority Data
Sep. 5, 2024 (KR) 10-2024-0121114

(51) Int. Cl. H10K 59/131; H10K 59/121; H10K 59/122; H10K 59/35

(52) U.S. Cl. CPC H10K 59/131; H10K 59/1213; H10K 59/122; H10K 59/353

(57) ABSTRACT

A display device including: a substrate including a display area and a peripheral area; sub-pixels positioned in the display area, each of the sub-pixels including a light-emitting device, a first transistor electrically connected to the light-emitting device, and a conductive layer that electrically connects the light-emitting device and the first transistor; and a first voltage line and a second voltage line, extending in parallel in a first direction, each applying a first voltage to sub-pixels of two adjacent rows among the plurality of sub-pixels, wherein the sub-pixels of the two rows are positioned between the first voltage line and the second voltage line, the conductive layers of the sub-pixels connected to the first voltage line extend toward the second voltage line in a second direction, and the conductive layers of the sub-pixels connected to the second voltage line extend toward the first voltage line in the second direction.

### CROSS-REFERENCE TO RELATED APPLICATION

This application claims priority under 35 U.S.C. § 119 to Korean Patent Application No. 10-2024-0121114, filed on Sep. 5, 2024, in the Korean Intellectual Property Office, the disclosure of which is incorporated by reference herein in its entirety.

### 1.Technical Field

One or more embodiments of the present disclosure relate to a display device.

### 2.Description of the Related Art

Recently, various lightweight and compact flat panel display devices have been developed. Flat panel display devices include liquid crystal display (LCD) devices, field emission display (FED) devices, plasma display panel (PDP) devices, and organic light-emitting display (OLED) devices.

Among flat panel display devices, OLED devices display images using organic light-emitting diodes, which emit light through the recombination of electrons and holes. These OLED devices are gaining attention as next generation displays due to their fast response speeds and low power consumption.

### SUMMARY

One or more embodiments of the present disclosure provide a display device with enhanced integration and higher resolution.

According to an embodiment of the present disclosure, there is provided a display device including: a substrate including a display area and a peripheral area adjacent to the display area; a plurality of sub-pixels positioned in the display area, each of the plurality of sub-pixels including a light-emitting device, a first transistor electrically connected to the light-emitting device, and a conductive layer that electrically connects the light-emitting device and the first transistor; and a first voltage line and a second voltage line, extending in parallel in a first direction, each applying a first voltage to sub-pixels of two adjacent rows among the plurality of sub-pixels, wherein the sub-pixels of the two rows are positioned between the first voltage line and the second voltage line, the conductive layers of the sub-pixels connected to the first voltage line extend toward the second voltage line in a second direction perpendicular to the first direction, and the conductive layers of the sub-pixels connected to the second voltage line extend toward the first voltage line in the second direction.

The light-emitting device includes a pixel electrode, a common electrode, and a middle layer positioned between the pixel electrode and the common electrode, wherein the light-emitting device includes an organic material and the pixel electrode is electrically connected to the conductive layer.

The display device further including: a pixel-defining layer covering a portion of the pixel electrode, the pixel-defining layer defining an opening.

The plurality of sub-pixels include first sub-pixels for emitting green light, second sub-pixels for emitting blue light, and third sub-pixels for emitting red light.

The first sub-pixels are arranged in a first column parallel to the second direction, the second sub-pixels are arranged in a second column parallel to the second direction, and the third sub-pixels are arranged in a third column parallel to the second direction.

The first sub-pixels, the second sub-pixels, and the third sub-pixels are arranged in a repeating sequence of the first column, the second column, and the third column.

A shape of the opening of each first sub-pixel is symmetrical with respect to a first virtual line that passes through a center of the opening of the first sub-pixel and extends in the first direction, and asymmetrical with respect to a second virtual line that passes through the center of the opening of the first sub-pixel and extends in the second direction.

The shape of the opening of each second sub-pixel is obtained by rotating the opening of each of the first sub-pixel by 180°.

A ratio of an area of the opening of the third sub-pixel to an area of the opening of the first sub-pixel is about 0.3 to about 0.7.

A shape of the opening of the third sub-pixel is symmetrical with respect to a first virtual line that passes through a center of the opening of the third sub-pixel and extends in the second direction, and symmetrical with respect to a second virtual line that passes through the center of the opening of the third sub-pixel and extends in the first direction.

According to an embodiment of the present disclosure, there is provided a display device including: a substrate including a display area and a peripheral area adjacent to the display area; and a plurality of sub-pixels positioned in the display area, each of the plurality of sub-pixels including an organic light-emitting device, and a first transistor electrically connected to the organic light-emitting device, wherein the plurality of sub-pixels includes first sub-pixels for emitting green light, second sub-pixels for emitting blue light, and third sub-pixels for emitting red light, and wherein a shape of a light-emitting area of each of the first sub-pixel is, symmetrical with respect to a first virtual line that passes through a center of the light-emitting area of the first sub-pixel and extends in a first direction and, and asymmetrical with respect to a second virtual line that passes through the center of the light-emitting area of the first sub-pixel and extends in a second direction perpendicular to the first direction.

A shape of a light-emitting area of each second sub-pixel is obtained by rotating the light-emitting area of each of the first sub-pixel by 180°.

A shape of a light-emitting area of each third sub-pixel is symmetrical with respect to a third virtual line that passes through a center of the light-emitting area of the third sub-pixel and extends in the first direction, and symmetrical with respect to a fourth virtual line that passes through a center of the light-emitting area of the third sub-pixel and extends in the second direction.

A ratio of a size of the light-emitting area of the third sub-pixel to a size of the light-emitting area of the first sub-pixel is about 0.3 to about 0.7.

Each of the plurality of sub-pixels further includes a conductive layer positioned between the organic light-emitting device and the first transistor and electrically connecting the organic light-emitting device and the first transistor to each other, and further including a first voltage line and a second voltage line extending in parallel in the first direction and each applying a first voltage to the sub-pixels of two adjacent rows among the plurality of sub-pixels, wherein the sub-pixels of the two rows are positioned between the first voltage line and the second voltage line.

The conductive layers of the sub-pixels that are electrically connected to the first voltage line extend toward the second voltage line in the second direction perpendicular to the first direction, and the conductive layers of the sub-pixels that are electrically connected to the second voltage line extend toward the first voltage line in the second direction.

The display device further including a second transistor and a third transistor that are positioned on a same layer between the first transistor and the organic light-emitting device.

The first transistor is a driving transistor, the second transistor is a switching transistor, and the third transistor is an initialization transistor.

The first sub-pixels are arranged in a first column parallel to the second direction, the second sub-pixels are arranged in a second column parallel to the second direction, and the third sub-pixels are arranged in a third column parallel to the second direction.

The first sub-pixels, the second sub-pixels, and the third sub-pixels are arranged in a repeating sequence of the first column, the second column, and the third column.

According to an embodiment of the present disclosure, there is provided an electronic device including: a display device wherein the display device includes, a substrate including a display area and a peripheral area positioned outside the display area; a plurality of sub-pixels positioned in the display area, each of the plurality of sub-pixels including a light-emitting device, a first transistor electrically connected to the light-emitting device, and a conductive layer electrically connecting the light-emitting device and the first transistor to each other; and a first voltage line and a second voltage line extending in parallel in a first direction and each applying a first voltage to sub-pixels of two adjacent rows among the plurality of sub-pixels, wherein the sub-pixels of the two rows are positioned between the first voltage line and the second voltage line, the conductive layers of the sub-pixels that are electrically connected to the first voltage line extend toward the second voltage line in a second direction perpendicular to the first direction, and the conductive layers of the sub-pixels that are electrically connected to the second voltage line extend toward the first voltage line in the second direction.

### BRIEF DESCRIPTION OF THE DRAWINGS

FIG. 1 is a plan view schematically illustrating a display device according to an embodiment of the present disclosure;

FIG. 2 is a block diagram schematically illustrating a structure of the display device shown in FIG. 1;

FIG. 3 is an equivalent circuit diagram of a sub-pixel of the display device shown in FIG. 1;

FIG. 4 is a layout schematically illustrating positions of thin film transistors and capacitors in the sub-pixel of the display device shown in FIG. 1;

FIG. 5 is a cross-sectional view schematically illustrating a portion of the display device shown in FIG. 1;

FIG. 6 is a plan view schematically illustrating an example of openings of a plurality of sub-pixels of the display device shown in FIG. 1;

FIG. 7 is a plan view schematically illustrating an example of openings of a first sub-pixel of the display device shown in FIG. 1;

FIG. 8 is a plan view schematically illustrating an example of openings of a third sub-pixel of the display device shown in FIG. 1;

FIG. 9 is a plan view schematically illustrating an example of two adjacent sub-pixels of the display device shown in FIG. 1; and

FIG. 10 is a view schematically illustrating an example of an electronic device including the display device according to embodiments that is implemented as a head mounted display.

### DETAILED DESCRIPTION OF THE EMBODIMENTS

Reference will now be made in detail to various embodiments, examples of which are illustrated in the accompanying drawings, where like reference numerals indicate like elements throughout. It should be noted that the present embodiments may have different forms and are not limited to the descriptions provided herein. Accordingly, the embodiments are described below with reference to the figures solely to explain aspects. In this context, the term “and/or” includes any and all combinations of one or more of the listed items. Expressions such as “at least one of,” when before a list of elements, apply to the entire list as a whole rather than to individual elements of the list.

In the following embodiments, terms such as “first” and “second” are used solely to distinguish one component from another and should not be interpreted as implying any specific order or limitation.

In the following embodiments, singular terms include plural terms unless the context clearly indicates otherwise.

In the following embodiments, terms such as “include” or “have” indicate that the features or components described in the specification are present. These terms do not preclude the possibility of adding one or more additional features or components.

In the following embodiments, when a film, region, component, or similar element is described as being “on” or “above” another element, this includes both cases where it is directly on or above the element and cases where another film, region, component, or similar element is interposed in between.

In the drawings, components may be exaggerated or reduced in size for convenience of explanation. For example, the size and thickness of each component depicted are arbitrarily shown for convenience purposes and should not be construed as limiting the scope of the present disclosure.

The present disclosure relates to a display device designed to enhance integration and resolution by leveraging an innovative arrangement of sub-pixels and voltage lines. The display device incorporates a substrate with a display area containing sub-pixels, each equipped with a light-emitting device, a transistor, and a conductive layer connecting these elements. The sub-pixels are organized such that their conductive layers extend alternately toward adjacent voltage lines, improving electrical connectivity and preventing shorts.

Additionally, the sub-pixels are optimized with asymmetrical and symmetrical opening designs for enhanced aperture ratios, which allow for greater light-emitting area density. This configuration not only improves resolution and integration but also reduces current density, leading to lower power consumption and extended lifespan of the sub-pixels. The design is particularly applicable to devices like OLED displays, suitable for a wide range of applications including head-mounted displays, smartphones, and other electronic devices.

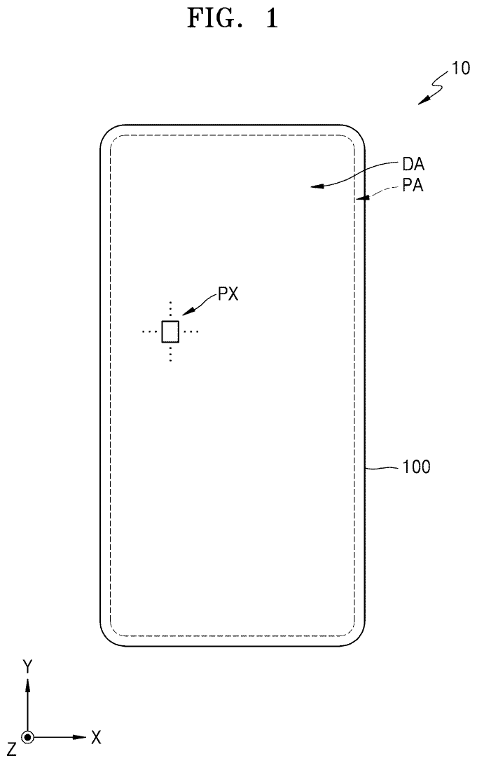

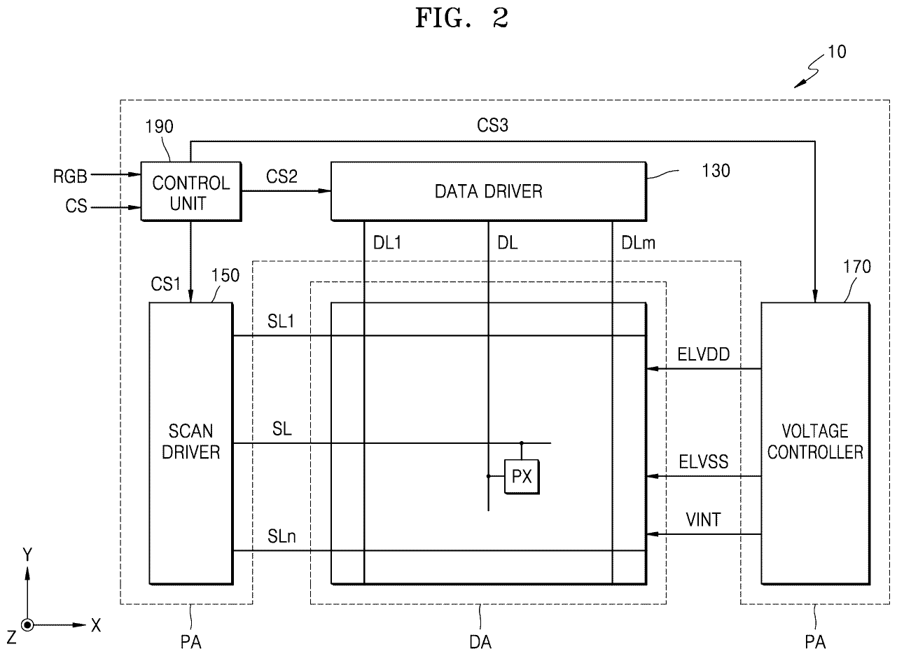

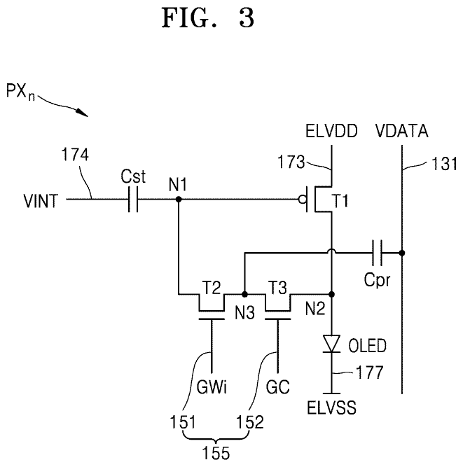

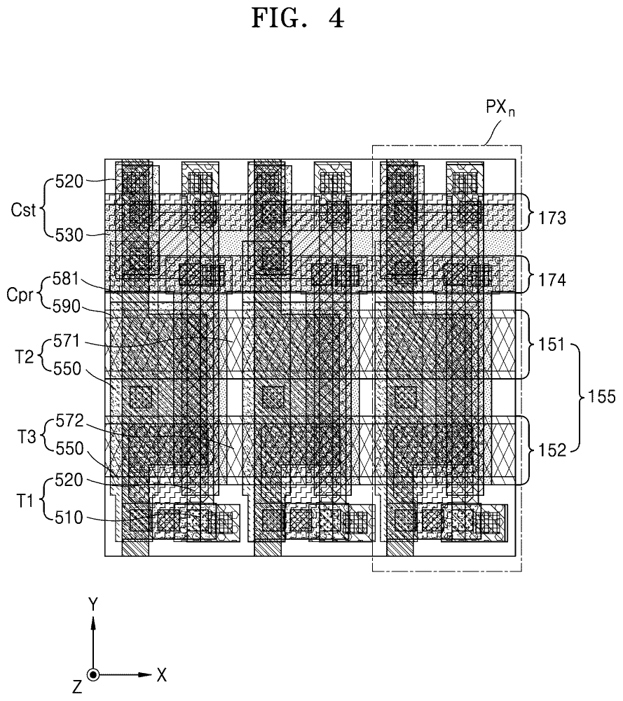

FIG. 1 is a plan view schematically illustrating a display device according to an embodiment of the present disclosure, FIG. 2 is a block diagram schematically illustrating a structure of the display device shown in FIG. 1, FIG. 3 is an equivalent circuit diagram of a sub-pixel of the display device shown in FIG. 1, and FIG. 4 is a layout schematically illustrating positions of thin film transistors and capacitors in the sub-pixel of the display device shown in FIG. 1.

First, referring to FIGS. 1 and 2, a display device 10 according to an embodiment may include a substrate 100 having a display area DA for displaying an image and a peripheral area PA positioned outside the display area DA.

A plurality of scan lines SL1, . . . , SLn extending in a first direction x, a plurality of data lines DL1, . . . , DLm extending in a second direction y vertically crossing the first direction x, and a plurality of sub-pixels PX may be arranged in the display area DA. In this regard, m and n may each be a natural number.

The wirings through which electrical signals are applied to the plurality of sub-pixels PX may include the plurality of scan lines SL1, . . . , SLn, the plurality of data lines DL1, . . . , DLm, etc. In an example embodiment, the plurality of scan lines SL1, . . . , SLn may be arranged in a plurality of rows extending in the first direction x to transmit a scan signal to the sub-pixels PX and the plurality of data lines DL1, . . . , DLm may be arranged in a plurality of columns extending in the second direction y to transmit a data signal to the sub-pixels PX. The plurality of sub-pixels PX may be positioned at cross points (e.g., intersections) of the plurality of scan lines SL1, . . . , SLn and the plurality of data lines DL1, . . . , DLm.

Each sub-pixel PX may include a light-emitting device and emit red, green, blue, or white light. In an example embodiment, each sub-pixel PX may include an organic light-emitting diode (OLED) as a light-emitting device.

A data driver 130 for providing data signals to the display area DA, a scan driver 150 for providing scan signals to the display area DA, a voltage controller 170 for controlling voltages applied to the display area DA, and a control unit 190 for controlling the data driver 130, the scan driver 150, and the voltage controller 170, etc. may be arranged in the peripheral area PA.

The voltage controller 170 may generate and control a first voltage ELVDD, a common voltage ELVSS, and an initialization voltage VINT that are applied to the display area DA.

Thus, the first voltage ELVDD, the common voltage ELVSS, and the initialization voltage VINT may be applied to the plurality of sub-pixels PX. In an example embodiment, the first voltage ELVDD may be a positive voltage, and the common voltage ELVSS may be a negative voltage or a ground voltage. In other words, the common voltage ELVSS may have a lower level than the first voltage ELVDD.

The control unit 190 may receive image signals RGB and a control signal CS from the outside (for example, a system board). The control unit 190 may convert the data format of the image signals RGB to comply with the interface specifications of the data driver 130, to generate image data. The control unit 190 may provide, to the data driver 130, the image data after converting its data format.

The control unit 190 may generate and output a first control signal CS1 and a second control signal CS2 in response to a control signal CS provided from the outside. The first control signal CS1 may be a scan control signal, and the second control signal CS2 may be a data control signal. The first control signal CS1 may be provided to the scan driver 150. The second control signal CS2 may be provided to the data driver 130.

The scan driver 150 may generate a plurality of scan signals in response to the first control signal CS1. The plurality of scan signals may be applied to the plurality of sub-pixels PX through the plurality of scan lines SL1, . . . , SLn.

The data driver 130 may generate a plurality of data voltages corresponding to the image data in response to the second control signal CS2. The plurality of data voltages may be applied to the plurality of sub-pixels PX through the data lines DL1, . . . , DLm. The data driver 130 may simultaneously provide the data voltages, generated for each sub-pixel row, to the data lines DL1, . . . , DLm, so that the data voltages are simultaneously provided to the plurality of sub-pixels PX.

The plurality of sub-pixels PXs may receive the plurality of data voltages in response to the plurality of scan signals. The plurality of sub-pixels PX may display an image by emitting light having a luminance corresponding to the plurality of data voltages. The plurality of sub-pixels PX may display the image by emitting light sequentially or simultaneously.

Referring to FIGS. 1 to 3, each of the plurality of sub-pixels PX may include a first transistor T1, a second transistor T2, a third transistor T3, and a light-emitting device OLED electrically connected to the first transistor T1.

Among the plurality of sub-pixels PX, the sub-pixel PX connected to an i-th scan line 155 of the plurality of scan lines SL1, . . . , SLn and a j-th data line 131 of the plurality of data lines DL1, . . . , DLm may be referred to as an n-th sub-pixel PXn. In this regard, i and j may be a natural number, respectively.

The i-th scan line may include a first scan line 151 and a second scan line 152. The first scan line 151 and the second scan line 152 may transmit scan signals GWi and GC to the n-th sub-pixel PXn, respectively.

The data line 131 may transmit a data voltage VDATA to the n-th sub-pixel PXn. The data voltage VDATA may have a voltage level corresponding to the image signal RGB that is input to the display device 10.

A first voltage line 173 may transmit the first voltage ELVDD to the n-th sub-pixel PXn, a common voltage line 177 may transmit the common voltage ELVSS to the n-th sub-pixel PXn, and an initialization voltage line 174 may transmit the initialization voltage VINT to the n-th sub-pixel PXn.

In an embodiment, the first transistor T1 may be a P-type transistor including a low-temperature polycrystalline silicon (LTPS) semiconductor layer. However, this is just an example, and the first transistor T1 may be an N-type transistor.

The second transistor T2 and the third transistor T3 may be a P-type transistor having an oxide semiconductor layer, respectively. However, this is just an example, and the second and/or third transistors T2 and T3 may be an N-type transistor.

The first transistor T1 may include a first gate electrode, a first driving electrode, and a second driving electrode. The first gate electrode of the first transistor T1 may be connected to a first node N1, the first driving electrode of the first transistor T1 may be connected to the first voltage line 173, and the second driving electrode of the first transistor T1 may be connected to a second node N2. The first transistor T1 may be referred to as a driving transistor.

The second transistor T2 may include a second gate electrode, a first switching electrode, and a second switching electrode. The second gate electrode of the second transistor T2 may be connected to the first scan line 151, the first switching electrode of the second transistor T2 may be connected to the first node N1, and the second switching electrode of the second transistor T2 may be connected to a third node N3. The second transistor T2 may be referred to as a switching transistor, a scan transistor, etc.

The third transistor T3 may include a third gate electrode, a first initialization electrode, and a second initialization electrode. The third gate electrode of the third transistor T3 may be connected to the second scan line 152, the first initialization electrode of the third transistor T3 may be connected to the third node N3, and the second initialization electrode of the third transistor T3 may be connected to the second node N2. The third transistor T3 may be referred to as an initialization transistor.

In an embodiment, each of the plurality of sub-pixels PX may further include a first capacitor Cst and a second capacitor Cpr.

A first electrode of the first capacitor Cst may be connected to the first node N1 and a second electrode of the first capacitor Cst may be connected to the initialization voltage line 174. The first capacitor Cst may be referred to as a storage capacitor.

The first capacitor Cst may store a voltage between the first node N1 and the initialization voltage line 174. The driving current flowing through the first transistor T1 may be determined by the voltage stored in the first capacitor Cst. The light-emitting diode (OLED) may emit light based on the driving current.

A first electrode of the second capacitor Cpr may be connected to the third node N3, and a second electrode of the second capacitor Cpr may be connected to the data line 131.

The second capacitor Cpr may store a voltage between the third node N3 and the data line 131. In some embodiments, the second capacitor Cpr may initialize the first voltage ELVDD by the second node N2 and the third transistor T3.

A first electrode of the light-emitting device OLED may be connected to the second node N2 and a second electrode the light-emitting device OLED may be connected to the common voltage line 177. The first electrode of the light-emitting device OLED may be referred to as an anode electrode or a pixel electrode, and the second electrode of the light-emitting device OLED may be referred to as a cathode electrode or a common electrode.

Referring to FIG. 4, the n-th sub-pixel PXn may include the first voltage line 173, the first scan line 151, the second scan line 152, and the initialization voltage line 174 that are extending in the first direction x.

In some embodiments, the second gate electrode or the second sub-gate electrode of the second transistor T2 of the n-th sub-pixel PXn may be connected to the first scan line 151 of the i-th scan line 155, the third gate electrode or the third sub-gate electrode of the third transistor T3 of the n-th sub-pixel PXn may be connected to the second scan line 152 of the i-th scan line 155, and the first driving electrode of the first transistor T1 of the n-th sub-pixel PXn may be connected to the first voltage line 173 to which the first voltage ELVDD is applied.

The second electrode of the first capacitor Cst of the n-th sub-pixel PXn may be connected to the initialization voltage line 174 to which the initialization voltage VINT is applied, and the second electrode of the second capacitor Cpr of the n-th sub-pixel PXn may be connected to the j-th data line 131 to which the data voltage VDATA is applied.

In an embodiment, an i-th scan signal GWi transmitted to the n-th sub-pixel PXn through the first scan line 151 may be sequentially generated in the scan driver 150.

In some embodiments, an i-th scan signal GC transmitted to the n-th sub-pixel PXn through the second scan line 152 may be a global gate signal for synchronizing a plurality of pixels PX. However, this is not limited thereto, and in another embodiment, the i-th scan signal GC transmitted through the second scan line 152 may be sequentially generated in the scan driver 150.

In an embodiment, longitudinal directions of the first scan line 151, the second scan line 152, the first voltage line 173, and the initialization voltage line 174 that are connected to the n-th sub-pixel PXn may be in parallel with the first direction x.

In some embodiments, the data line 131 for applying the data voltage VDATA to the n-th sub-pixel PXn may be arranged in the second direction y perpendicular to the first direction x.

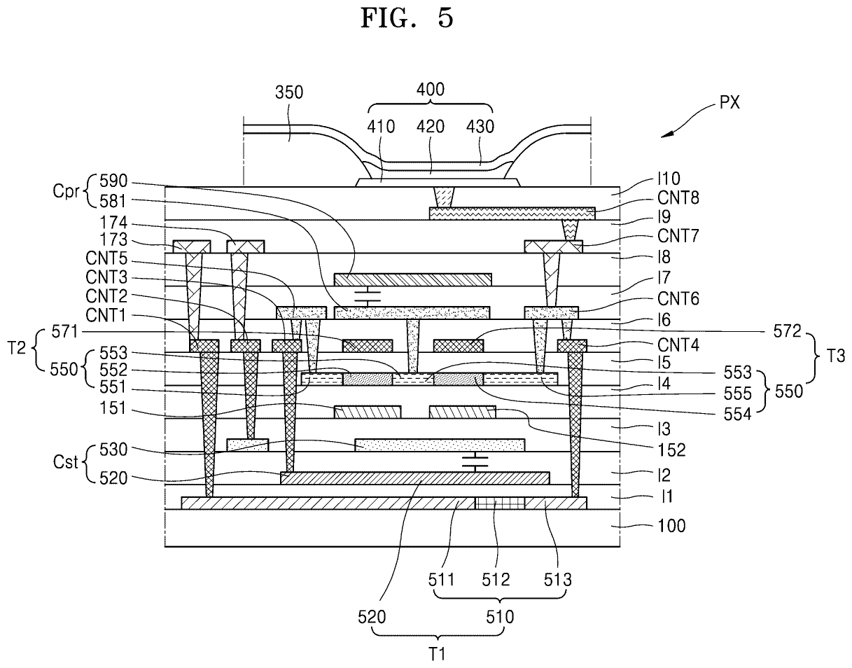

FIG. 5 is a cross-sectional view schematically illustrating a portion of the display device shown in FIG. 1. For example, FIG. 5 may show an example of the sub-pixel PX illustrated in FIGS. 1 to 4.

Referring to FIG. 5 together with FIGS. 2 to 4, the sub-pixel PX according to an embodiment may include a substrate 100, a first transistor T1 on the substrate 100, a second transistor T2 and a third transistor T3 over the first transistor T1, a light-emitting device OLED that is positioned over the second transistor T2 and the third transistor T3 and electrically connected to the first transistor T1, a first capacitor Cst, and a second capacitor Cpr. The second transistor T2 and the third transistor T3 may be positioned on the same layer.

More specifically, the substrate 100 may be made of a transparent glass material containing silicon oxide (SiO₂) as a main component. However, it is not limited thereto, and the substrate 100 may include a transparent plastic material. The plastic material may include polyethersulfone (PES), polyacrylate (PAR), polyetherimide (PEI), polyethylene naphthalate (PEN), polyethyeleneterepthalate (PET), polyphenylene sulfide (PPS), polyallylate, polyimide, polycarbonate (PC), cellulose triacetate (TAC), cellulose acetate propionate (CAP), etc.

A first semiconductor layer 510 may be formed on the substrate 100. The first semiconductor layer 510 may include a first source region 511, a first drain region 513, and a first channel region 512 between the first source region 511 and the first drain region 513.

In some embodiments, the first semiconductor layer 510 may include the first source region 511 and the first drain region 513 formed by doping impurities at both sides of the first channel region 512. In an embodiment, the impurities may vary according to the type of the first transistor T1 and include N-type impurities or P-type impurities. In other words, the first channel region 512, the first source region 511 positioned at a first side of the first channel region 512, and the first drain region 513 positioned at a second side of the first channel region 512 are referred to as the first semiconductor layer 510.

The first source region 511 and the first drain region 513, which are doped with impurities, may be interpreted as a source electrode (or the first driving electrode) and a drain electrode (or the second driving electrode) of the first transistor T1, respectively, in some cases. In some embodiments, the positions of the first source region 511 and the first drain region 513 may be interchangeable, depending on the type of the impurities doped into the first semiconductor layer 510.

The first semiconductor layer 510 may include polycrystalline silicon. For example, the first semiconductor layer 510 may include low-temperature polycrystalline silicon (LTPS), but is not limited thereto, and the first semiconductor layer 510 may include semiconductor oxide.

In an alternative embodiment, a buffer layer may be positioned between the substrate 100 and the first semiconductor layer 510. The buffer layer may prevent impurity diffusion during the crystallization process for forming polycrystalline silicon, thereby improving its characteristics, and may also provide a flat surface.

A first insulating layer 11 may be formed on the first semiconductor layer 510 to cover the first semiconductor layer 510. A first conductive layer including a first gate electrode 520 may be formed on the first insulating layer 11. In a plan view, the area of the first gate electrode 520 may be larger than the area of the first channel region 512 of the first transistor T1.

The first gate electrode 520, along with the first semiconductor layer 510, may form the first transistor T1. The first transistor T1 may receive the first voltage ELVDD in the first source region 511 to provide a driving current to the light-emitting device 400.

In some embodiments, the first gate electrode 520 may function as the first electrode 520 of the first capacitor Cst. Accordingly, increasing the integration level of the display device 10 may allow for larger areas for the first capacitor Cst and the first transistor T1, enabling the provision of high-quality images. However, the present disclosure is not limited thereto. In another embodiment, the first electrode 520 of the first capacitor Cst may be an independent component separated from the first gate electrode 520 of the first transistor T1.

A second insulating layer 12 may be formed on the first conductive layer to cover the first conductive layer. A second conductive layer including the second electrode 530 of the first capacitor Cst may be formed on the second insulating layer 12. The second electrode 530 and the first electrode 520 of the first capacitor Cst may together form the first capacitor Cst.

A third insulating layer 13 may be formed on the second conductive layer to cover the second conductive layer. A third conductive layer including the first scan line 151 and the second scan line 152 to which the scan signals GWi and GC are applied, respectively, may be formed on the third insulating layer 13.

A fourth insulating layer 14 may be formed on the third conductive layer to cover the third conductive layer. A second semiconductor layer 550 may be formed on the fourth insulating layer 14. The second semiconductor layer 550 may include a second source region 551, a second channel region 552, a second drain region 553, a third source region 553, a third channel region 554, and a third drain region 555.

The second channel region 552 may be positioned between the second source region 551 and the second drain region 553, and the third channel region 554 may be positioned between the third source region 553 and the third drain region 555. In some embodiments, the second drain region 553 and the third source region 553 may refer to the same region.

Depending on the impurities doped into the second semiconductor layer 550, the positions of the second source region 551 and the second drain region 553 may be interchanged. Similarly, the positions of the third source region 553 and the third drain region 555 may also be interchanged based on the impurities doped into the second semiconductor layer 550.

The second semiconductor layer 550 may be a layer including semiconductor oxide, but is not limited thereto, and the second semiconductor layer 550 may also be a layer including polycrystalline silicon, for example, low-temperature polycrystalline silicon (LTPS).

A fifth insulating layer 15 may be formed on the second semiconductor layer 550 to cover the second semiconductor layer 550. A fourth conductive layer may be formed on the fifth insulating layer 15 to include a plurality of contacts CNT1, CNT2, CNT3 and CNT4, a second gate electrode 571, and a third gate electrode 572.

The second gate electrode 571 and the third gate electrode 572 may overlap the second channel region 552 and the third channel region 554, respectively. The second gate electrode 571 may form the second transistor T2 together with the second source region 551, the second channel region 552, and the second drain region 553. In some embodiments, the third gate electrode 572 may form the third transistor T3, which is positioned on the same layer as the second transistor T2, together with the third source region 553, the third channel region 554, and the third drain region 555.

In an embodiment, the first scan line 151 and the second scan line 152, positioned on the third insulating layer 13 between the first transistor T1 and the second transistor T2 and located on the same layer, may be referred to as a second sub-gate electrode 151 and a third sub-gate electrode 152, respectively.

The second sub-gate electrode 151 and the third sub-gate electrode 152, together with the second gate electrode 571 and the third gate electrode 572, may form the dual gate of the second transistor T2 and the dual gate of the third transistor T3, respectively. As a result, the scan signals GWi and GC may be applied to the second transistor T2 and the third transistor T3, respectively.

The second sub-gate electrode 151 may overlap the second gate electrode 571, and an area of the second sub-gate electrode 151 may be larger than that of the second gate electrode 571 in a plan view. In some embodiments, the third sub-gate electrode 152 may overlap the third gate electrode 572, and an area of the third sub-gate electrode 152 may be larger than that of the third gate electrode 572 in a plan view.

When the second transistor T2 and the third transistor T3 include dual gates, the current flowing through these transistors can be more precisely controlled, and their switching speed can be enhanced due to the interaction of the dual gates. This allows the second transistor T2 and the third transistor T3 to operate with lower power consumption.

A sixth insulating layer 16 may be formed on the fourth conductive layer to cover the fourth conductive layer. A fifth conductive layer including a plurality of contacts CNT5 and CNT6 and the first electrode 581 of the second capacitor Cpr may be formed on the sixth insulating layer 16.

The first electrode 581 of the second capacitor Cpr may be electrically connected between the second channel region 552 and the third channel region 554 of the second semiconductor layer 550 through a contact hole. The contact hole may expose at least a portion of a region between the second channel region 552 and the third channel region 554.

In other words, the first electrode 581 of the second capacitor Cpr may be connected to the second transistor T2 and the third transistor T3 through a single contact hole, rather than being electrically connected, respectively, through two different contact holes, to improve the integration degree of the display device 10.

A fifth contact CNT5 may be electrically connected to the first gate electrode 520 through a third contact CNT3 on the fifth insulating layer 15. In some embodiments, the fifth contact CNT5 may be electrically connected to the second source region 551 of the second transistor T2. Accordingly, the fifth contact CNT5, the first gate electrode 520, and the second source region 551 may be electrically connected to each other. For example, the fifth contact CNT5 may be the first node N1 shown in FIG. 3.

A seventh insulating layer 17 may be formed on the fifth conductive layer to cover the fifth conductive layer. A sixth conductive layer including the second electrode 590 of the second capacitor Cpr may be formed on the seventh insulating layer 17.

The second electrode 590 of the second capacitor Cpr may overlap the first electrode 581 of the second capacitor Cpr. In some embodiments, the second electrode 590 of the second capacitor Cpr may be form the second capacitor Cpr together with the first electrode 581 of the second capacitor Cpr.

In some embodiments, the second electrode 590 of the second capacitor Cpr may include the data line 131 to which the data voltage VDATA is applied.

An eighth insulating layer 18 may be formed on the sixth conductive layer to cover the sixth conductive layer. A seventh conductive layer including the first voltage line 173 to which the first voltage ELVDD is applied, the initialization voltage line 174 to which the initialization voltage VINT is applied, and a seventh contact CNT7 may be formed on the eighth insulating layer 18.

The first voltage line 173 may be connected to the first source region 511 of the first transistor T1 through a first contact CNT1 on the fifth insulating layer 15. Accordingly, the first voltage ELVDD may be applied to the first source region 511 of the first transistor T1.

The initialization voltage line 174 may be connected to the second electrode 530 of the first capacitor Cst through the second contact CNT2 on the fifth insulating layer 15. Accordingly, the first capacitor Cst may store the initialization voltage VINT.

Each of the first insulating layer 11, the second insulating layer 12, the third insulating layer 13, the fourth insulating layer 14, the fifth insulating layer 15, the sixth insulating layer 16, the seventh insulating layer 17, and the eighth insulating layer 18 may include silicon nitride and/or silicon oxide.

A ninth insulating layer 19 may be formed on the seventh conductive layer to cover the seventh conductive layer. An eighth conductive layer including an eighth contact CNT8 may be formed on the ninth insulating layer 19.

The eighth contact CNT8 may be electrically connected to the seventh contact CNT7 positioned on the eighth insulating layer 18. The seventh contact CNT7 may be electrically connected to the sixth contact CNT6 positioned on the sixth insulating layer 16. In some embodiments, the sixth contact CNT6 may be electrically connected to the third drain region 555 of the third transistor T3, and the sixth contact CNT6 may be electrically connected to the first drain region 513 of the first transistor T1 through the fourth contact CNT4 positioned on the fifth insulating layer 15. In some embodiments, the eighth contact CNT8 may be electrically connected to a pixel electrode 410 of the light-emitting device 400.

In other words, the pixel electrode 410 of the light-emitting device 400 may be electrically connected to the first drain region 513 of the first transistor T1 and the third drain region 555 of the third transistor T3 through the eighth contact CNT8. For example, the eighth contact CNT8 may be the second node N2 shown in FIG. 3.

A tenth insulating layer 110 may be formed on the eighth conductive layer to cover the eighth conductive layer. The light-emitting device 400, which includes the pixel electrode 410, a common electrode 430, and a middle layer 420 arranged between the pixel electrode 410 and the common electrode 430 and having an emission layer, may be positioned on the tenth insulating layer 110. The light-emitting device 400 may be, for example, an organic light-emitting diode OLED including organic material.

In an embodiment, the pixel electrode 410 may be an anode of the organic light-emitting diode OLED and the common electrode 430 may be a cathode of the organic light-emitting diode OLED. However, the present disclosure is not limited thereto, and depending on the driving method of the display device, the pixel electrode 410 may be a cathode of the organic light-emitting diode OLED, and the common electrode 430 may be an anode of the organic light-emitting diode OLED. Holes and electrons are injected into the middle layer 420 from the pixel electrode 410 and the common electrode 430, respectively. The injected holes and electrons combine to form excitons, which transition from an excited state to a ground state, emitting light in the process.

The ninth insulating layer 19 and the tenth insulating layer 110 may each include organic material such as an imide-based polymer, a general-purpose polymer such as polymethylmethacrylate (PMMA) and polystyrene (PS), a polymer derivative having phenolic groups, an acrylic polymer, an aryl ether-based polymer, an amide-based polymer, a fluorine-based polymer, a p-xylene-based polymer, a vinyl alcohol-based polymer, and a blend thereof, or may include a stack layer of the organic material and inorganic material.

The first to eighth conductive layers may each include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

In an embodiment, the pixel electrode 410 may be a (semi) transparent electrode or a reflective electrode. When the pixel electrode 410 is the (semi) transparent electrode, the pixel electrode 410 may include, for example, indium tin oxide (ITO), indium zinc oxide (IZO), zinc oxide (ZnO), indium oxide (In2O3), indium gallium oxide (IGO), and aluminum zinc oxide (AZO). When the pixel electrode 410 is the reflective electrode, the pixel electrode 410 may include a reflective layer including one of silver (Ag), magnesium (Mg), aluminum (Al), platinum (Pt), palladium (Pd), gold (Au), nickel (Ni), neodymium (Nd), iridium (Ir), chromium (Cr), and a composition thereof, and a layer including indium tin oxide (ITO), indium zinc oxide (IZO), zinc oxide (ZnO), indium oxide (In2O3), indium gallium oxide (IGO), or aluminum zinc oxide (AZO). However, the present disclosure is not limited thereto, and the pixel electrode 410 may include various materials and its structure may also be modified in various ways, such as a single layer structure and a multilayer structure.

A pixel-defining layer 350 covering a peripheral portion of the pixel electrode 410 may be arranged on the tenth insulating layer 110. The pixel-defining layer 350 may have an opening corresponding to each pixel and exposing at least a portion of the organic light-emitting device OLED therethrough, to thereby define the pixel. In an embodiment, the opening may be a light-emitting area. In some embodiments, the pixel-defining layer 350 may increase the distance between the common electrode 430 and the peripheral portion of the pixel electrode 410, to prevent an electric arc therebetween. The pixel-defining layer 350 may include an organic material such as polyimide and hexamethyldisiloxane (HMDSO).

The middle layer 420 may be formed on a portion of the pixel electrode 410 that is exposed through the opening of the pixel-defining layer 350. The middle layer 420 may include a low-molecular or high-molecular substance. When including the low-molecular substance, the middle layer 420 may have a single structure or a stacked complex structure of a hole injection layer (HIL), a hole transport layer (HTL), an emission layer (EML), an electron transport layer (ETL), and an electron injection layer (EIL), and may include various organic materials, such as copper phthalocyanine (CuPc), naphthalene (N), N-di(naphthalene-1-yl)-N, N′-diphenyl-benzidine (N′-Di(naphthalene-1-yl)-N, N′-diphenyl-benzidine (NPB), tris-8-hydroxyquinoline aluminum (Alq3), etc. Those layers may be formed by a vacuum deposition process.

When including high-molecular substance, the middle layer 420 may have a structure including a hole transport layer (HTL) and an emission layer (EML). In an embodiment, the hole transport layer may include poly(3,4-ethylenedioxythiophene) (PEDOT), and the emission layer may include a polymer material such as poly-phenylenevinylene (PPV) and polyfluorene. The structure of the middle layer 420 is not limited thereto, and the middle layer 420 may have various structures. For example, the middle layer 420 may include an integrated layer across a plurality of the pixel electrodes 410, and a patterned layer corresponding to each of the plurality of pixel electrodes 410.

The common voltage ELVSS may be applied to the common electrode 430, and the common electrode 430 may cover the display area (DA in FIG. 1). In other words, the common electrode 430 may be integrally formed to cover a plurality of light-emitting devices 400. The common electrode 430 may be a (semi) transparent electrode or a reflective electrode. When being the (semi) transparent electrode, the common electrode 430 may include a layer, which includes a metal having a small work function such as lithium (Li), calcium (Ca), lithium fluoride (LiF)/calcium (Ca), lithium fluoride (LiF)/aluminum (Al), aluminum (Al), silver (Ag), magnesium (Mg), and a composition thereof, and a (semi) transparent conductive layer which includes indium tin oxide (ITO), indium zinc oxide (IZO), zinc oxide (ZnO), indium oxide (In2O3), etc. When being the reflective electrode, the common electrode 430 may include a layer including lithium (Li), calcium (Ca), lithium fluoride (LiF)/calcium (Ca), lithium fluoride (LiF)/aluminum (Al), aluminum (Al), silver (Ag), magnesium (Mg), and a composition thereof. However, the composition and material of the common electrode 430 are not limited thereto and various modifications are possible.

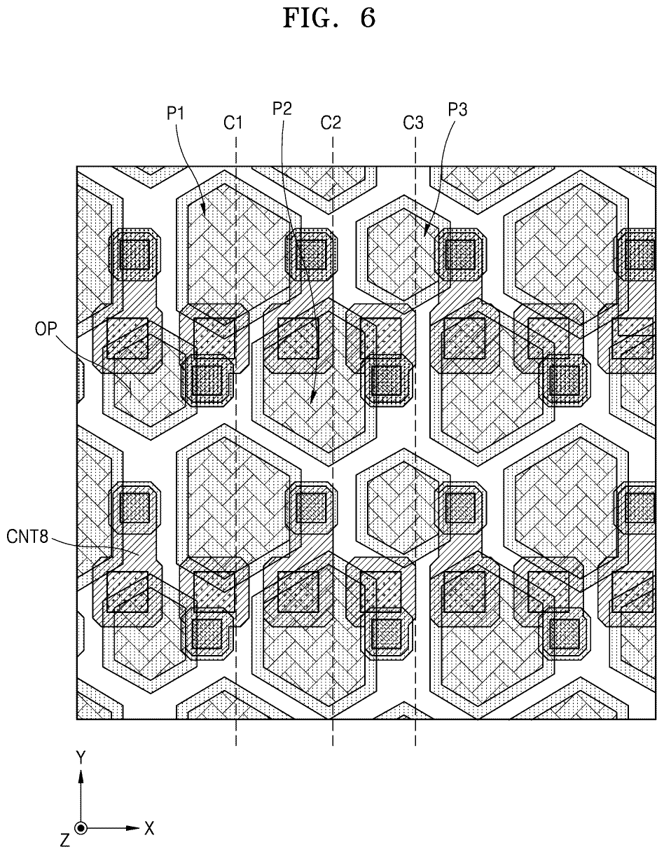

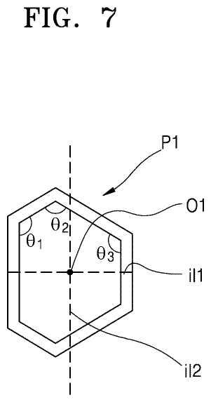

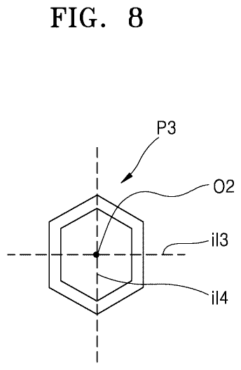

FIG. 6 is a plan view schematically illustrating an example of openings of a plurality of sub-pixels of the display device shown in FIG. 1, FIG. 7 is a plan view schematically illustrating an example of openings of a first sub-pixel of the display device shown in FIG. 1, and FIG. 8 is a plan view schematically illustrating an example of openings of a third sub-pixel of the display device shown in FIG. 1.

Referring to FIGS. 6 to 8, a plurality of sub-pixels PX may include first sub-pixels P1 emitting green light, second sub-pixels P2 emitting blue light, and third sub-pixels P3 emitting red light.

The first sub-pixels P1 may be arranged in a first column C1 parallel to the second direction y, the second sub-pixels P2 may be arranged in a second column C2 parallel to the second direction y, and the third sub-pixels P3 may be arranged in a third column C3 parallel to the second direction y.

In an embodiment, the first sub-pixels P1, the second sub-pixels P2, and the third sub-pixels P3 may be arranged in a repeating sequence along the first column C1, the second column C2, and the third column C3. In other words, the first sub-pixels P1 in the first column C1, the second sub-pixels P2 in the second column C2, and the third sub-pixels P3 in the third column C3 may be arranged sequentially in the first direction x. This arrangement may then be repeated in order along the first direction x. However, this is merely an example and does not limit the arrangement order of the sub-pixels. In another embodiment, the second sub-pixels P2, the first sub-pixels P1, and the third sub-pixels P3 may be arranged sequentially in the first direction x.

Generally, the aperture ratio is defined as the ratio of the area of the opening OP of the sub-pixel PX to the total area of a single pixel in a plan view. A single pixel may include the first sub-pixel P1, the second sub-pixel P2, and the third sub-pixel P3, representing the smallest repeating unit in the display area.

When the openings OP of the sub-pixels PX are shaped as regular hexagons, the combined aperture ratios of the first sub-pixel P1, the second sub-pixel P2, and the third sub-pixel P3 within a single pixel may be about 0.2 to about 0.3. However, if the openings OP are not shaped as regular hexagons, the pixel density may increase, resulting in a combined aperture ratio of the first sub-pixel P1, the second sub-pixel P2, and the third sub-pixel P3 in a single pixel to be about 0.35 to about 0.5. Accordingly, the light-emitting areas of the plurality of sub-pixels PX form a dense structure, enhancing the integration level and resolution of the display device.

As the sum of the aperture ratios of the first sub-pixel P1, the second sub-pixel P2, and the third sub-pixel P3 in a single pixel increases, the current density required to emit light of the same intensity from the sub-pixel PX decreases. Consequently, the electrical energy consumed by the sub-pixel PX is reduced, leading to an extended lifespan of the sub-pixel PX. For example, when the openings OP of the first sub-pixel P1, the second sub-pixel P2, and the third sub-pixel P3 are not shaped as regular hexagons, the lifespan of the display device may increase by more than double compared to when the openings OP of all the sub-pixels PX are regular hexagons.

When the openings OP of the first sub-pixel P1, the second sub-pixel P2, and the third sub-pixel P3 are not shaped as regular hexagons, the aperture ratio of the first sub-pixel P1 may be about 0.1 to about 0.2, the aperture ratio of the second sub-pixel P2 may be about 0.1 to about 0.2, and the aperture ratio of the third sub-pixel P3 may be about 0.05 to about 0.1. In some embodiments, the ratio of the area of the opening OP of the third sub-pixel P3 to the area of the opening OP of the first sub-pixel P1 may be about 0.3 to about 0.7.

The shape of the opening OP of the first sub-pixel P1 may not be a regular hexagon. In an embodiment, the opening OP of the first sub-pixel P1 may have a shape that is symmetrical with respect to a virtual line il1 passing through a center O1 of the opening OP and extending in the first direction x, but asymmetrical with respect to a virtual line il2 passing through the center O1 and extending in the second direction y perpendicular to the first direction x.

In some embodiments, the angles between two adjacent sides of the opening OP of the first sub-pixel P1 on one side of the virtual line il1 extending in the first direction x are denoted as θ1, θ2, and θ3 in clockwise order. In this configuration, the angles θ2 and θ3 are substantially the same, while θ1 differs from θ2. In other words, the opening OP of the first sub-pixel P1 may have a shape where a portion of the regular hexagon is removed along one side parallel to the second direction y.

However, the present disclosure is not limited to this configuration. The angles of θ1, θ2, and θ3 may be different from one another, and the opening OP of the first sub-pixel P1 may take on other shapes, provided that the aperture ratio is higher than that of a regular hexagonal shape. This allows for improved density of the sub-pixels PX.

In another embodiment, the shape of the opening OP of the first sub-pixel P1 may be symmetrical with respect to the virtual line il2 passing through the center O1 of the opening OP and extending in the second direction y, while being asymmetrical with respect to the virtual line il1 passing through the center O1 and extending in the first direction x perpendicular to the second direction y.

In another embodiment, the shape of the opening OP of the first sub-pixel P1 may be asymmetrical with respect to the virtual line il1 passing through the center O1 of the opening OP and extending in the first direction x, while being asymmetrical with respect to a virtual line il2 passing through the center O1 and extending in the second direction y perpendicular to the first direction x.

The opening OP of the second sub-pixel P2 may not have a regular hexagonal shape. In an embodiment, the shape of the opening OP of the second sub-pixel P2 is identical to that of the first sub-pixel P1 but rotated 180° clockwise. However, the present disclosure is not limited thereto. For example, the opening OP of the second sub-pixel P2 may take on any shape, provided that its aperture ratio is higher than that of a regular hexagonal shape, thereby improving the density of the sub-pixels PX. In another embodiment, the shape of the opening OP of the second sub-pixel P1 may be unrelated to the shape of the first sub-pixel P1.

The shape of the opening OP of the third sub-pixel P3 may not be a regular hexagon. In an embodiment, the shape of the opening OP of the third sub-pixel P3 may be symmetrical with respect to a virtual line il3 passing through a center O2 of the opening OP of the third sub-pixel P3 and extending in the first direction x, while being asymmetrical with respect to a virtual line il4 passing through the center O2 of the opening OP of the third sub-pixel P3 and extending in the second direction y perpendicular to the first direction x. However, the present disclosure is not limited thereto. For example, the opening OP of the third sub-pixel P3 may take any shape, provided its aperture ratio is higher than that a regular hexagonal shape, thereby enhancing the density of the sub-pixels PX. Specifically, the opening OP of the third sub-pixel P3 may have a shape where a regular hexagon extends in the second direction y.

In another embodiment, the shape of the opening OP of the third sub-pixel P3 may be asymmetrical with respect to the virtual line il3 passing through the center O2 of the opening OP of the third sub-pixel P3 and extending in the first direction x, while being asymmetrical with respect to the virtual line il4 passing through the center O2 of the opening OP of the third sub-pixel P3 and extending in the second direction y perpendicular to the first direction x.

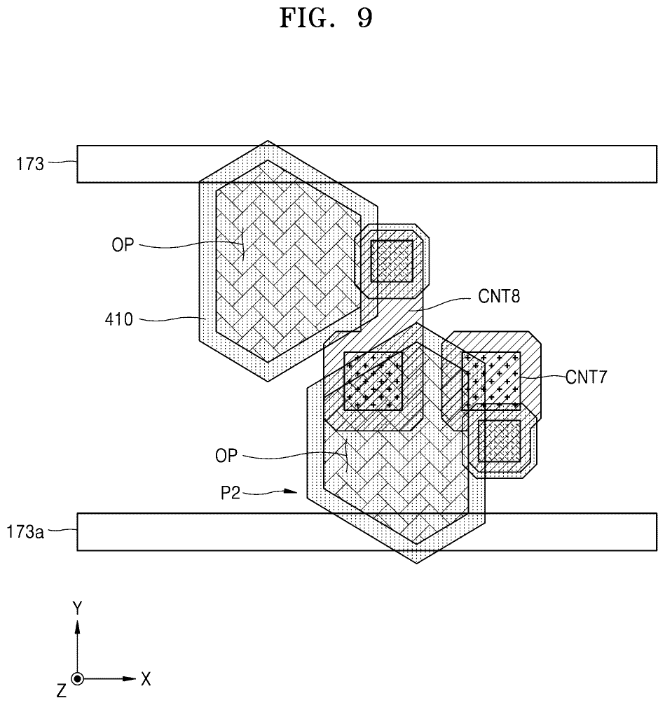

FIG. 9 is a plan view schematically illustrating an example of two adjacent sub-pixels of the display device shown in FIG. 1.

Referring to FIG. 9 together with FIG. 5, a plurality of first voltage lines 173 to which the first voltage ELVDD is applied may be parallel to second voltage lines 173a to which the first voltage ELVDD is applied. In an embodiment, the first voltage line 173 and the second voltage line 173a may be repeatedly arranged in the second direction y. Accordingly, the first voltage line 173 and the second voltage line 173a may apply the first voltage ELVDD to the sub-pixels PX in two adjacent rows located between the first voltage line 173 and the second voltage line 173a among the plurality of sub-pixels PX, respectively.

In some embodiments, the extension direction of the eighth conductive layer, which includes the eighth contact CNT8 for electrically connecting the light-emitting device 400 to the first transistor T1, may be opposite in the direction between the sub-pixels PX in two adjacent rows among the plurality of sub-pixels PX.

In some embodiments, the eighth conductive layer of the sub-pixels PX electrically connected to the first voltage line 173 may extend toward the second voltage line 173a in the second direction y perpendicular to the first direction x, and the eighth conductive layer of the sub-pixels PX electrically connected to the second voltage line 173a may extend toward the first voltage line 173 in the second direction y.

As described above, when the openings OP of the sub-pixels PX are not regular hexagons, the aperture ratio may increase, and accordingly, the degree of integration of a single pixel may increase. However, if a plurality of sub-pixels PX does not include an eighth conductive layer extending in different directions, and a seventh contact CNT7, which is positioned on the same layer as the first voltage line 173 and the second voltage line 173a, is directly connected to the pixel electrode 410 through a contact hole, the seventh contact CNT7, the first voltage line 173 and the second voltage line 173a may come into contact with each other and become electrically shorted due to the high pixel density.

In some embodiments, unlike the configuration illustrated in FIG. 9, when the eighth conductive layer of the sub-pixels PX electrically connected to the first voltage line 173 does not extend toward the second voltage line 173a in the second direction y, but instead extends toward the first voltage line 173, the seventh contact CNT7, which is connected to the eighth contact CNT8, may become electrically shorted by making contact with the first voltage line 173 that is positioned on the same layer as the seventh contact CNT7.

Accordingly, when the eighth contact CNT8 extends in different directions in adjacent pixel rows, the electrical short described above may be prevented. At the same time, the degree of integration and the resolution of the display device may be improved due to the denser structure of the light-emitting areas in the plurality of sub-pixels PX.

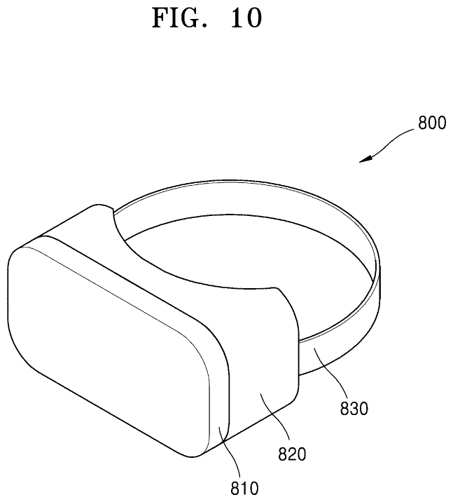

FIG. 10 is a view schematically illustrating an example of an electronic device including the display device according to embodiments that is implemented as a head mounted display.

Referring to FIG. 10, an electronic device according to an embodiment may include a display device and may be implemented as a head mounted display (HMD) 800. The HMD 800 may include a display unit 810, a body unit 820, and a mounting unit 830.

In an embodiment, the display unit 810 may include the display device according to the embodiments of FIGS. 1 to 7 to implement a screen. The body unit 820 may include a controller for applying a scan signal and a data signal to the display unit 810, a touch sensor, an acoustic sensor, etc. The HMD 800 may be mounted on the user by the mounting unit 830.

However, this is for illustrative purposes, and the electronic device is not limited to the HMD 800. For example, the electronic device may be any device incorporating the display, such as a virtual reality (VR) device, mobile phone, smartphone, tablet computer, digital television, 3D TV, personal computer (PC), home electronics, laptop, personal digital assistant (PDA), portable multimedia player (PMP), digital camera, music player, portable game console, navigation device, and so on.

According to an embodiments, as the light-emitting areas of the sub-pixels form a denser structure, the degree of integration and resolution of the display device may be improved.

However, the effects achievable through the present disclosure are not limited those described above, and other technical effects not explicitly mentioned will be readily understood by those skilled in the art from the description provided.

Although the present disclosure has been described using specific embodiments and drawings, the present disclosure is not limited thereto Various modifications and variations can be made within the scope of the technical concept of the present disclosure and the equivalent scope of the claims outlined below, as will be apparent to those skilled in the relevant art.

What is claimed is:

1. A display device comprising:
a substrate including a display area and a peripheral area adjacent to the display area;
a plurality of sub-pixels positioned in the display area, each of the plurality of sub-pixels including a light-emitting device, a first transistor electrically connected to the light-emitting device, and a conductive layer that electrically connects the light-emitting device and the first transistor; and
a first voltage line and a second voltage line, extending in parallel in a first direction, each applying a first voltage to sub-pixels of two adjacent rows among the plurality of sub-pixels,
wherein the sub-pixels of the two rows are positioned between the first voltage line and the second voltage line,
the conductive layers of the sub-pixels connected to the first voltage line extend toward the second voltage line in a second direction perpendicular to the first direction, and
the conductive layers of the sub-pixels connected to the second voltage line extend toward the first voltage line in the second direction.

2. The display device of claim 1, wherein
the light-emitting device includes a pixel electrode, a common electrode, and a middle layer positioned between the pixel electrode and the common electrode, wherein the light-emitting device includes an organic material and the pixel electrode is electrically connected to the conductive layer.

3. The display device of claim 2, further comprising:
a pixel-defining layer covering a portion of the pixel electrode,
the pixel-defining layer defining an opening.

4. The display device of claim 3, wherein
the plurality of sub-pixels include first sub-pixels for emitting green light, second sub-pixels for emitting blue light, and third sub-pixels for emitting red light.

5. The display device of claim 4, wherein
the first sub-pixels are arranged in a first column parallel to the second direction, the second sub-pixels are arranged in a second column parallel to the second direction, and the third sub-pixels are arranged in a third column parallel to the second direction.

6. The display device of claim 5, wherein
the first sub-pixels, the second sub-pixels, and the third sub-pixels are arranged in a repeating sequence of the first column, the second column, and the third column.

7. The display device of claim 4, wherein
a shape of the opening of each first sub-pixel is,
symmetrical with respect to a first virtual line that passes through a center of the opening of the first sub-pixel and extends in the first direction, and
asymmetrical with respect to a second virtual line that passes through the center of the opening of the first sub-pixel and extends in the second direction.

8. The display device of claim 7, wherein
the shape of the opening of each second sub-pixel is obtained by rotating the opening of each of the first sub-pixel by 180°.

9. The display device of claim 4, wherein
a ratio of an area of the opening of the third sub-pixel to an area of the opening of the first sub-pixel is about 0.3 to about 0.7.

10. The display device of claim 4, wherein
a shape of the opening of the third sub-pixel is,
symmetrical with respect to a first virtual line that passes through a center of the opening of the third sub-pixel and extends in the second direction, and
symmetrical with respect to a second virtual line that passes through the center of the opening of the third sub-pixel and extends in the first direction.

11. A display device comprising:
a substrate including a display area and a peripheral area adjacent to the display area; and
a plurality of sub-pixels positioned in the display area, each of the plurality of sub-pixels including an organic light-emitting device, and a first transistor electrically connected to the organic light-emitting device,
wherein the plurality of sub-pixels includes first sub-pixels for emitting green light, second sub-pixels for emitting blue light, and third sub-pixels for emitting red light, and
wherein a shape of a light-emitting area of each first sub-pixel is,
symmetrical with respect to a first virtual line that passes through a center of the light-emitting area of the first sub-pixel and extends in a first direction and, and
asymmetrical with respect to a second virtual line that passes through the center of the light-emitting area of the first sub-pixel and extends in a second direction perpendicular to the first direction.

12. The display device of claim 11, wherein
a shape of a light-emitting area of each second sub-pixel is obtained by rotating the light-emitting area of each first sub-pixel by 180°.

13. The display device of claim 11, wherein
a shape of a light-emitting area of each third sub-pixel is,
symmetrical with respect to a third virtual line that passes through a center of the light-emitting area of the third sub-pixel and extends in the first direction, and
symmetrical with respect to a fourth virtual line that passes through a center of the light-emitting area of the third sub-pixel and extends in the second direction.

14. The display device of claim 11, wherein
a ratio of a size of the light-emitting area of the third sub-pixel to a size of the light-emitting area of the first sub-pixel is about 0.3 to about 0.7.

15. The display device of claim 11, wherein
each of the plurality of sub-pixels further includes,
a conductive layer positioned between the organic light-emitting device and the first transistor and electrically connecting the organic light-emitting device and the first transistor to each other, and
further comprising a first voltage line and a second voltage line extending in parallel in the first direction and each applying a first voltage to the sub-pixels of two adjacent rows among the plurality of sub-pixels,
wherein the sub-pixels of the two rows are positioned between the first voltage line and the second voltage line.

16. The display device of claim 15, wherein
the conductive layers of the sub-pixels that are electrically connected to the first voltage line extend toward the second voltage line in the second direction perpendicular to the first direction, and
the conductive layers of the sub-pixels that are electrically connected to the second voltage line extend toward the first voltage line in the second direction.

17. The display device of claim 15, further comprising:
a second transistor and a third transistor that are positioned on a same layer between the first transistor and the organic light-emitting device.

18. The display device of claim 17, wherein
the first transistor is a driving transistor, the second transistor is a switching transistor, and the third transistor is an initialization transistor.

19. The display device of claim 11, wherein
the first sub-pixels are arranged in a first column parallel to the second direction, the second sub-pixels are arranged in a second column parallel to the second direction, and the third sub-pixels are arranged in a third column parallel to the second direction.

20. An electronic device comprising:
a display device wherein the display device includes,
a substrate including a display area and a peripheral area positioned outside the display area;
a plurality of sub-pixels positioned in the display area, each of the plurality of sub-pixels including a light-emitting device, a first transistor electrically connected to the light-emitting device, and a conductive layer electrically connecting the light-emitting device and the first transistor to each other; and
a first voltage line and a second voltage line extending in parallel in a first direction and each applying a first voltage to sub-pixels of two adjacent rows among the plurality of sub-pixels,
wherein the sub-pixels of the two rows are positioned between the first voltage line and the second voltage line,
the conductive layers of the sub-pixels that are electrically connected to the first voltage line extend toward the second voltage line in a second direction perpendicular to the first direction, and
the conductive layers of the sub-pixels that are electrically connected to the second voltage line extend toward the first voltage line in the second direction.
